(19) United States
(12) Patent Application Publication
(10) Pub. No.: US 2023/0378325 A1
(43) Pub. Date: Nov. 23, 2023

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Sheng-Hsuan LIN, Hsinchu (TW); Feng-Yu CHANG, Kaohsiung (TW); Shu-Lan CHANG, Hsinchu (TW); I Lee, Hsinchu (TW); Chun-Yen LIAO, Hsinchu (TW)

(21) Appl. No.: 17/750,750

(22) Filed: May 23, 2022

(51) Int. Cl. H01L 29/66; H01L 29/78; H01L 29/40; H01L 29/51

(52) U.S. Cl. CPC H01L 29/66795; H01L 29/785; H01L 29/66545; H01L 29/401; H01L 29/517; H01L 29/6656

(57) ABSTRACT

Semiconductor device structure and methods of forming the same are described. The structure includes a dielectric layer disposed over an epitaxy source/drain region and a conductive feature disposed in the dielectric layer. The conductive feature includes a metal liner including a first material and a metal fill surrounded by the metal liner. The metal fill includes the first material having a first grain size. The conductive feature further includes a metal cap disposed on the metal liner and the metal fill, and the metal cap includes the first material having a second grain size different from the first grain size.

### BACKGROUND

The semiconductor integrated circuit (IC) industry has experienced exponential growth. Technological advances in IC materials and design have produced generation of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs.

Accompanying the scaling down of devices, manufacturers have begun using new and different materials and/or combination of materials to facilitate the scaling down of devices. Scaling down, alone and in combination with new and different materials, has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device structure, in accordance with some embodiments.

FIGS. 2-6 are cross-sectional side views of various stages of manufacturing the semiconductor device structure of FIG. 1 taken along cross-section A-A, in accordance with some embodiments.

FIGS. 7A-7H are enlarged views of a portion of the semiconductor device structure of FIG. 6 during various manufacturing stages, in accordance with some embodiments.

FIG. 7I is a cross-sectional side view of one of various stages of manufacturing the semiconductor device structure of FIG. 1 taken along cross-section B-B, in accordance with some embodiments.

FIG. 8 is a cross-sectional side view of one of various stages of manufacturing the semiconductor device structure, in accordance with some embodiments.

FIG. 9 is a cross-sectional side view of an interconnect structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Generally, the present disclosure provides example embodiments relating to conductive features, such as metal contacts, vias, lines, etc., and methods for forming those conductive features. Example embodiments described herein are described in the context of forming conductive features in middle of the line (MOL) processing for a fin field effect transistor (FinFET). Other embodiments may be implemented in other contexts, such as forming conductive features in back end of the line (BEOL), or with different devices, such as planar field effect transistors (FETs), vertical gate all around (VGAA) FETs, horizontal gate all around (HGAA) FETs, bipolar junction transistors (BJTs), diodes, capacitors, inductors, resistors, etc. Implementations of some aspects of the present disclosure may be used in other processes and/or in other devices.

Some variation of the example methods and structures are described. A person having ordinary skill in the art will readily understand other modifications that may be made that are contemplated within the scope of other embodiments. Although method embodiments may be described in a particular order, various other method embodiments may be performed in any logical order and may include fewer or more steps than what is described herein. In some figures, some reference numbers of components or features illustrated therein may be omitted to avoid obscuring other components or features; this is for ease of depicting the figures.

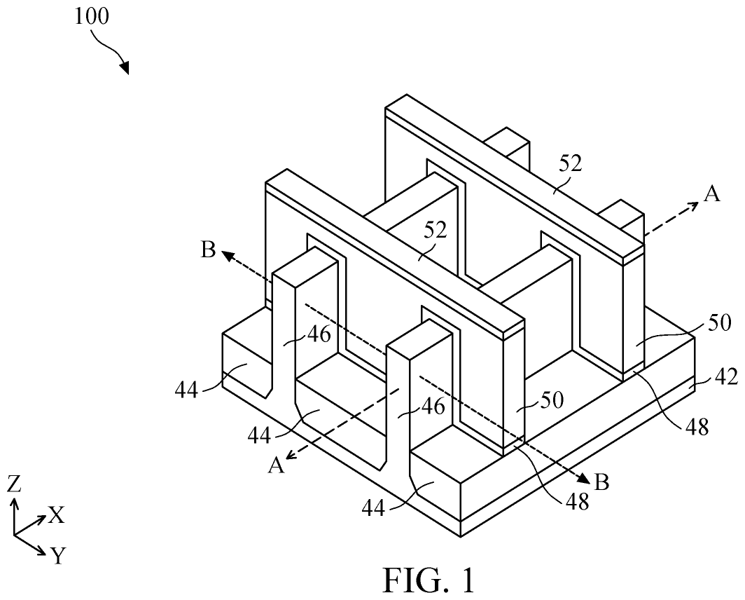

FIGS. 1 through 6 illustrate views of respective semiconductor device structure 100 at respective stages during an example method for forming conductive features in accordance with some embodiments. FIG. 1 illustrates a perspective view of the semiconductor device structure at a stage of the example method. The semiconductor device structure 100, as described in the following, is used in the implementation of FinFETs. Other structures may be implemented in other example embodiments.

The semiconductor device structure 100 includes first and second fins 46 formed on a semiconductor substrate 42, with respective isolation regions 44 on the semiconductor substrate 42 between neighboring fins 46. First and second dummy gate stacks are along respective sidewalls of and over the fins 46. The first and second dummy gate stacks each include an interfacial dielectric 48, a dummy gate 50, and a mask 52.

The semiconductor substrate 42 may be or include a bulk semiconductor substrate, a semiconductor-on-insulator (SOI) substrate, or the like, which may be doped (e.g., with a p-type or an n-type dopant) or undoped. In some embodiments, the semiconductor material of the semiconductor substrate 42 may include an elemental semiconductor such as silicon (Si) or germanium (Ge); a compound semiconductor; an alloy semiconductor; or a combination thereof.

The fins 46 are formed in the semiconductor substrate 42. For example, the semiconductor substrate 42 may be etched, such as by appropriate photolithography and etch process, such that trenches are formed between neighboring pairs of fins 46 and such that the fins 46 protrude from the semiconductor substrate 42. Isolation regions 44 are formed with each being in a corresponding trench. The isolation regions 44 may include or be an insulating material such as an oxide (such as silicon oxide), a nitride, the like, or a combination thereof. The insulating material may then be recessed after being deposited to form the isolation regions 44. The insulating material is recessed using an acceptable etch process such that the fins 46 protrude from between neighboring isolation regions 44, which may, at least in part, thereby delineate the fins 46 as active areas on the semiconductor substrate 42. The fins 46 may be formed by other processes, and may include homoepitaxial and/or heteroepitaxial structures, for example.

The dummy gate stacks are formed on the fins 46. In a replacement gate process as described herein, the interfacial dielectrics 48, dummy gates 50, and masks 52 for the dummy gate stacks may be formed by sequentially forming respective layers by appropriate deposition processes, for example, and then patterning those layers into the dummy gate stacks by appropriate photolithography and etch processes. For example, the interfacial dielectrics 48 may include or be silicon oxide, silicon nitride, the like, or multilayers thereof. The dummy gates 50 may include or be silicon (e.g., polysilicon) or another material. The masks 52 may include or be silicon nitride, silicon oxynitride, silicon carbon nitride, the like, or a combination thereof.

In other examples, instead of and/or in addition to the dummy gate stacks, the gate stacks can be operational gate stacks (or more generally, gate structures) in a gate-first process. In a gate-first process, the interfacial dielectric 48 may be a gate dielectric layer, and the dummy gate 50 may be a gate electrode. The gate dielectric layers, gate electrodes, and masks 52 for the operational gate stacks may be formed by sequentially forming respective layers by appropriate deposition processes, and then patterning those layers into the gate stacks by appropriate photolithography and etch processes. For example, the gate dielectric layers may include or be silicon oxide, silicon nitride, a high-k dielectric material, the like, or multilayers thereof. A high-k dielectric material may have a k value greater than about 7.0, and may include a metal oxide of or a metal silicate of hafnium (Hf), aluminum (Al), zirconium (Zr), lanthanum (La), magnesium (Mg), barium (Ba), titanium (Ti), lead (Pb), multilayers thereof, or a combination thereof. The gate electrodes may include or be silicon (e.g., polysilicon, which may be doped or undoped), a metal-containing material (such as titanium, tungsten, aluminum, ruthenium, or the like), a combination thereof (such as a silicide (which may be subsequently formed), or multiple layers thereof. The masks 52 may include or be silicon nitride, silicon oxynitride, silicon carbon nitride, the like, or a combination thereof.

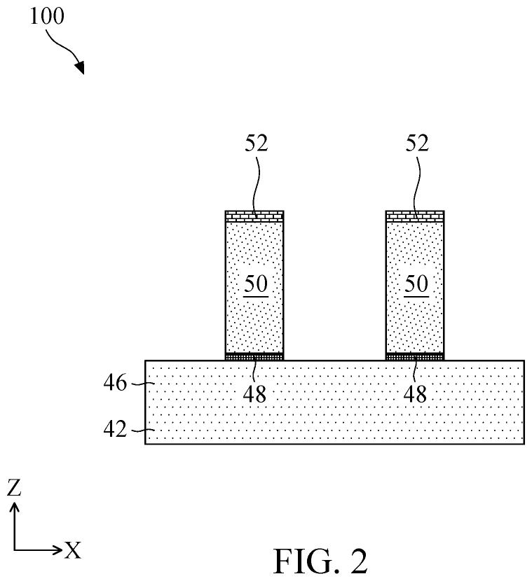

FIG. 1 further illustrates a reference cross-section that is used in later figures. Cross-section A-A is in a plane along, e.g., channels in the fin 46 between opposing source/drain regions. The FIGS. 2 through 6 illustrate cross-sectional views at various stages of processing in various example methods corresponding to cross-section A-A. FIG. 2 illustrates a cross-sectional view of the semiconductor device structure 100 of FIG. 1 at the cross-section A-A.

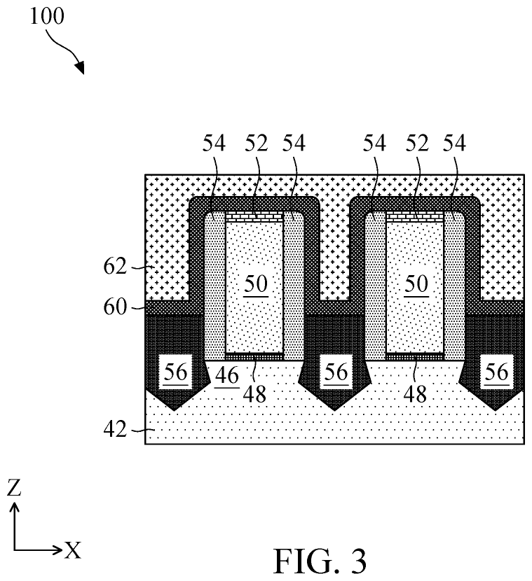

FIG. 3 illustrates the formation of gate spacers 54, epitaxy source/drain regions 56, a contact etch stop layer (CESL) 60, and a dielectric layer 62. Gate spacers 54 are formed along sidewalls of the dummy gate stacks (e.g., sidewalls of the interfacial dielectrics 48, dummy gates 50, and masks 52) and over the fins 46. The gate spacers 54 may be formed by conformally depositing, by an appropriate deposition process, one or more layers for the gate spacers 54 and anisotropically etching the one or more layers, for example. The one or more layers for the gate spacers 54 may include or be silicon oxygen carbide, silicon nitride, silicon oxynitride, silicon carbon nitride, the like, multi-layers thereof, or a combination thereof.

Recesses are then formed in the fins 46 on opposing sides of the dummy gate stacks (e.g., using the dummy gate stacks and gate spacers 54 as a mask) by an etch process. The etch process can be isotropic or anisotropic, or further, may be selective with respect to one or more crystalline planes of the semiconductor substrate 42. Hence, the recesses can have various cross-sectional profiles based on the etch process implemented. The epitaxy source/drain regions 56 are formed in the recesses. The epitaxy source/drain regions 56 may include or be silicon germanium, silicon carbide, silicon phosphorus, silicon carbon phosphorus, pure or substantially pure germanium, a III-V compound semiconductor, a II-VI compound semiconductor, or the like. The epitaxy source/drain regions 56 may be formed in the recesses by an appropriate epitaxial growth or deposition process. In some examples, epitaxy source/drain regions 56 can be raised with respect to the fin 46, and can have facets, which may correspond to crystalline planes of the semiconductor substrate 42.

A person having ordinary skill in the art will also readily understand that the recessing and epitaxial growth may be omitted, and that source/drain regions may be formed by implanting dopants into the fins 46 using the dummy gate stacks and gate spacers 54 as masks. In some examples where epitaxy source/drain regions 56 are implemented, the epitaxy source/drain regions 56 may also be doped, such as by in situ doping during epitaxial growth and/or by implanting dopants into the epitaxy source/drain regions 56 after epitaxial growth. Hence, a source/drain region may be delineated by doping (e.g., by implantation and/or in situ during epitaxial growth, if appropriate) and/or by epitaxial growth, if appropriate, which may further delineate the active area in which the source/drain region is delineated.

The CESL 60 is conformally deposited, by an appropriate deposition process, on surfaces of the epitaxy source/drain regions 56, sidewalls and top surfaces of the gate spacers 54, top surfaces of the masks 52, and top surfaces of the isolation regions 44. Generally, an etch stop layer (ESL) can provide a mechanism to stop an etch process when forming, e.g., contacts or vias. An ESL may be formed of a dielectric material having a different etch selectively from adjacent layers or components. The CESL 60 may include or be silicon nitride, silicon carbon nitride, silicon carbon oxide, carbon nitride, the like, or a combination thereof.

The dielectric layer 62 is deposited, by an appropriate deposition process, on the CESL 60. In some embodiments, the dielectric layer 62 is a first interlayer dielectric (ILD). The dielectric layer 62 may include or be silicon dioxide, a low-k dielectric material (e.g., a material having a dielectric constant lower than silicon dioxide), silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOₓC_{y}, spin-on-glass, spin-on-polymers, silicon carbon material, a compound thereof, a composite thereof, the like, or a combination thereof.

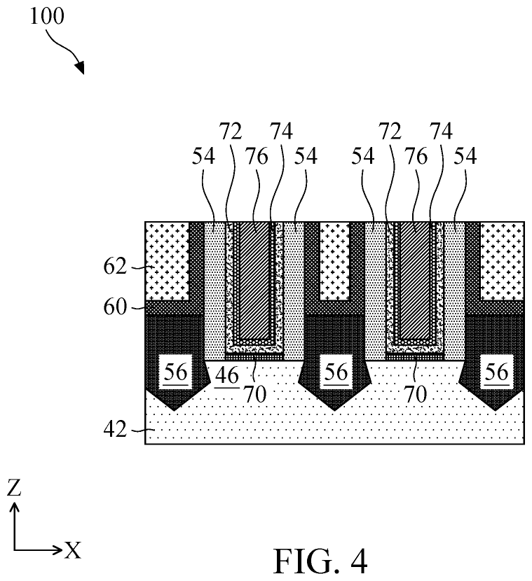

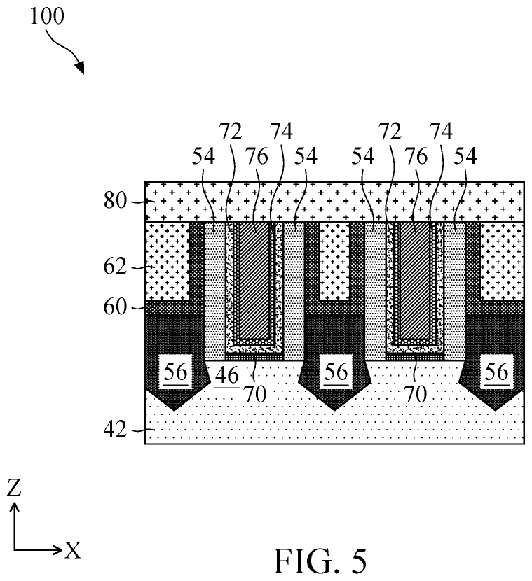

The dielectric layer 62 may be planarized after being deposited, such as by a chemical mechanical polishing (CMP). In a gate-first process, a top surface of the dielectric layer 62 may be above the upper portions of the CESL 60 and the gate stacks, and processing described below with respect to FIGS. 4 and 5 may be omitted. Hence, the upper portions of the CESL 60 and dielectric layer 62 may remain over the gate stacks.

FIG. 4 illustrates the replacement of the dummy gate stacks with replacement gate structures. The dielectric layer 62 and CESL 60 are formed with top surfaces coplanar with top surfaces of the dummy gates 50. A planarization process, such as a CMP, may be performed to level the top surfaces of the dielectric layer 62 and CESL 60 with the top surfaces of the dummy gates 50. The CMP may also remove the masks 52 (and, in some instances, upper portions of the gate spacers 54) on the dummy gates 50. Accordingly, top surfaces of the dummy gates 50 are exposed through the dielectric layer 62 and the CESL 60.

With the dummy gates 50 exposed through the dielectric layer 62 and the CESL 60, the dummy gates 50 are removed, such as by one or more etch processes. The dummy gates 50 may be removed by an etch process selective to the dummy gates 50, where the interfacial dielectrics 48 act as ESLs, and subsequently, the interfacial dielectrics 48 can optionally be removed by a different etch process selective to the interfacial dielectrics 48. Recesses are formed between gate spacers 54 where the dummy gate stacks are removed, and channel regions of the fins 46 are exposed through the recesses.

The replacement gate structures are formed in the recesses where the dummy gate stacks were removed. The replacement gate structures each include, as illustrated, an interfacial dielectric 70, a gate dielectric layer 72, one or more optional conformal layers 74, and a gate conductive fill material 76. The interfacial dielectric 70 is formed on sidewalls and top surfaces of the fins 46 along the channel regions. The interfacial dielectric 70 can be, for example, the interfacial dielectric 48 if not removed, an oxide (e.g., silicon oxide) formed by thermal or chemical oxidation of the fin 46, and/or an oxide (e.g., silicon oxide), nitride (e.g., silicon nitride), and/or another dielectric layer.

The gate dielectric layer 72 can be conformally deposited in the recesses where dummy gate stacks were removed (e.g., on top surfaces of the isolation regions 44, on the interfacial dielectric 70, and sidewalls of the gate spacers 54) and on the top surfaces of the dielectric layer 62, the CESL 60, and gate spacers 54. The gate dielectric layer 72 can be or include silicon oxide, silicon nitride, a high-k dielectric material (examples of which are provided above), multilayers thereof, or other dielectric material.

Then, the one or more optional conformal layers 74 can be conformally (and sequentially, if more than one) deposited on the gate dielectric layer 72. The one or more optional conformal layers 74 can include one or more barrier and/or capping layers and one or more work-function tuning layers. The one or more barrier and/or capping layers can include a nitride, silicon nitride, carbon nitride, and/or aluminum nitride of tantalum and/or titanium; a nitride, carbon nitride, and/or carbide of tungsten; the like; or a combination thereof. The one or more work-function tuning layer may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

A layer for the gate conductive fill material 76 is formed over the one or more optional conformal layers 74 (e.g., over the one or more work-function tuning layers), if implemented, and/or the gate dielectric layer 72. The layer for the gate conductive fill material 76 can fill remaining recesses where the dummy gate stacks were removed. The layer for the gate conductive fill material 76 may be or include a metal-containing material such as tungsten, cobalt, aluminum, ruthenium, copper, multi-layers thereof, a combination thereof, or the like. Portions of the layer for the gate conductive fill material 76, one or more optional conformal layers 74, and gate dielectric layer 72 above the top surfaces of the dielectric layer 62, the CESL 60, and gate spacers 54 are removed, such as by a CMP. The replacement gate structures including the gate conductive fill material 76, one or more optional conformal layers 74, gate dielectric layer 72, and interfacial dielectric 70 may therefore be formed as illustrated in FIG. 4.

FIG. 5 illustrates the formation of dielectric layer 80 over the dielectric layer 62, CESL 60, gate spacers 54, and replacement gate structures. Although not illustrated, in some examples, an ESL may be deposited over the dielectric layer 62, etc., and the dielectric layer 80 may be deposited over the ESL. If implemented, the ESL may include or be silicon nitride, silicon carbon nitride, silicon carbon oxide, carbon nitride, the like, or a combination thereof. In some embodiments, the dielectric layer 80 is a second ILD. The dielectric layer 80 may include or be silicon dioxide, a low-k dielectric material, silicon oxynitride, PSG, BSG, BPSG, USG, FSG, OSG, SiOₓC_{y}, spin-on-glass, spin-on-polymers, silicon carbon material, a compound thereof, a composite thereof, the like, or a combination thereof.

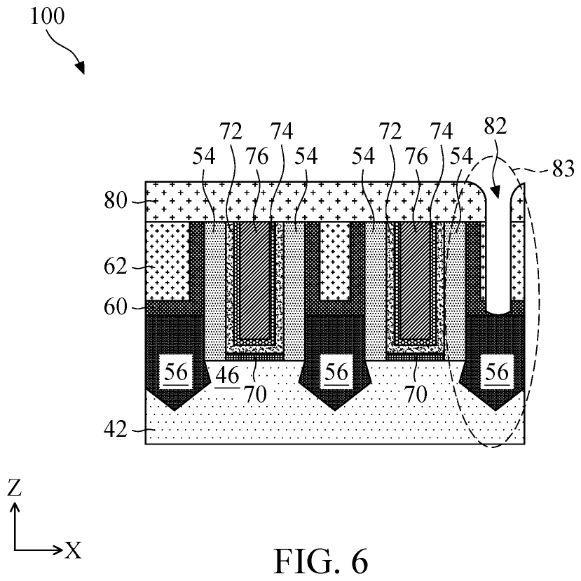

FIG. 6 illustrates the formation of openings 82 (one is shown). The openings 82 are formed through the dielectric layer 80, the dielectric layer 62, and the CESL 60 to expose at least a portion of an epitaxy source/drain region 56. The dielectric layer 80, the dielectric layer 62, and the CESL 60 may be patterned, for example, using photolithography and one or more etch processes, to form the openings 82.

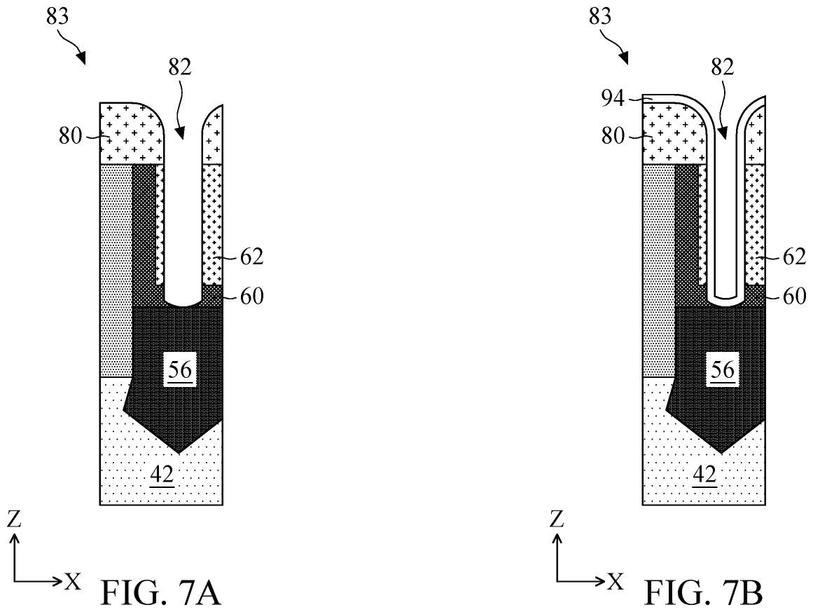

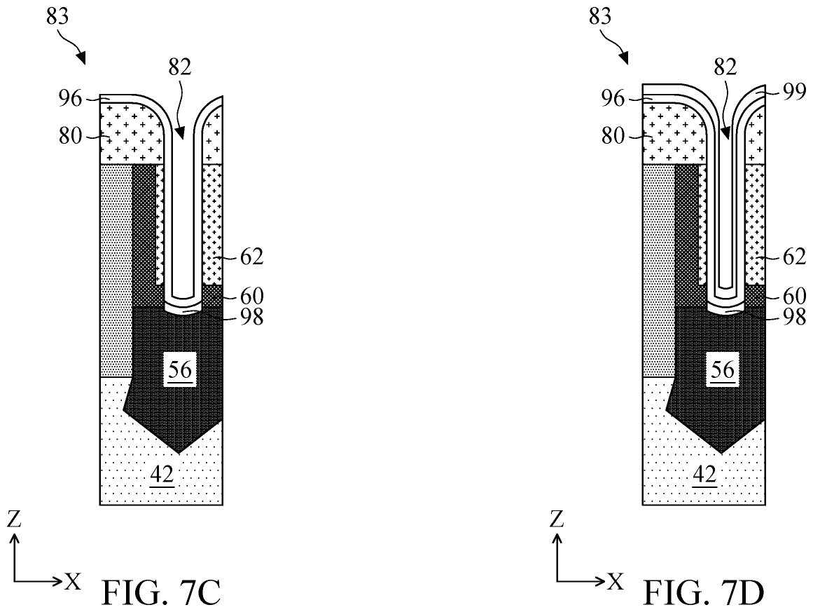

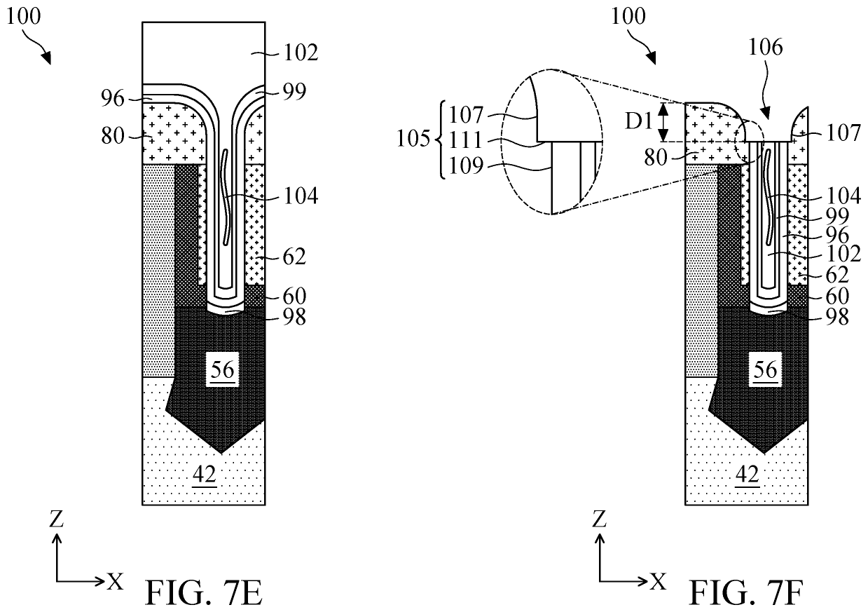

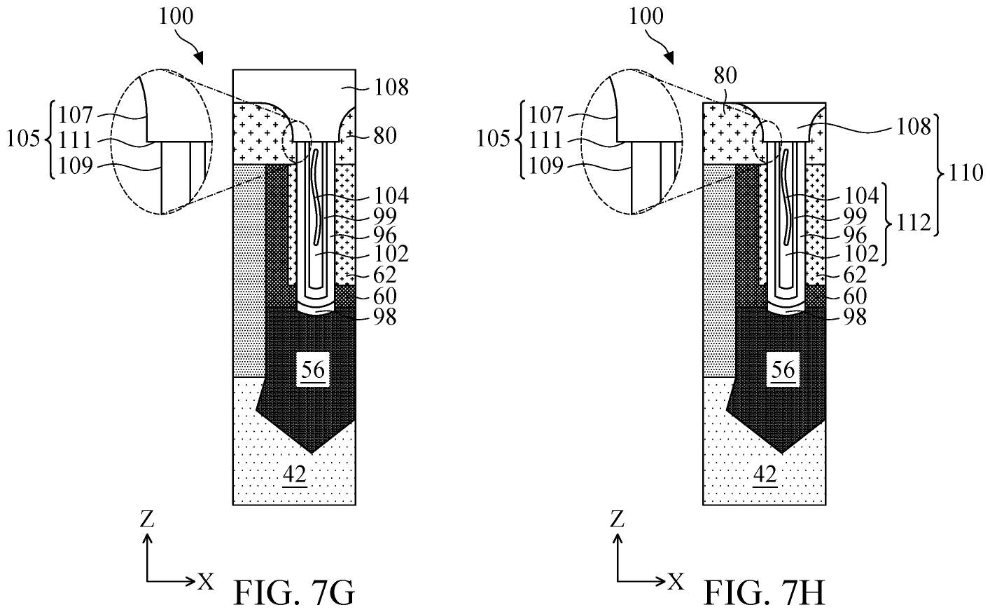

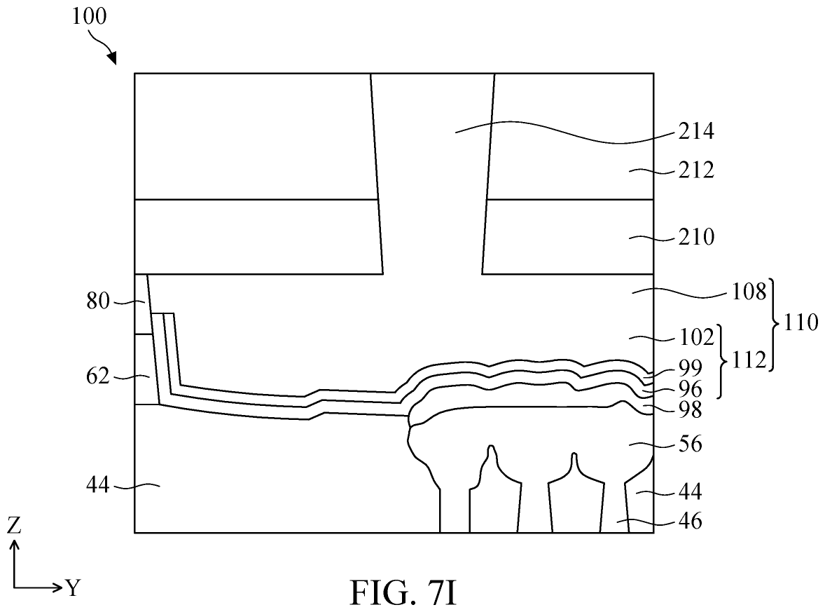

FIGS. 7A-7H are enlarged views of a portion 83 of the semiconductor device structure 100 of FIG. 6 during various manufacturing stages, in accordance with some embodiments. FIG. 7A is an enlarged view of the portion 83 of the semiconductor device structure 100 shown in FIG. 6. Next, as shown in FIG. 7B, a metal layer 94 is formed in the opening 82 and on the dielectric layer 80. The metal layer 94 can be conformally deposited in the openings 82 (e.g., on sidewalls of the openings 82 and exposed surface of the epitaxy source/drain region 56) and over the dielectric layer 80. The metal layer 94 may be or include titanium, tantalum, the like, or a combination thereof, and may be deposited by atomic layer deposition (ALD), chemical vapor deposition (CVD), physical vapor deposition (PVD), or another deposition technique.

As shown in FIG. 7C, a silicide region 98 may be formed on the epitaxy source/drain region 56 by reacting an upper portion of the epitaxy source/drain region 56 with the metal layer 94. An anneal can be performed to facilitate the reaction of the epitaxy source/drain region 56 with the metal layer 94 to form the silicide region 98. The silicide region 98 may have a thickness ranging from about 2 nm to about 9 nm.

In some embodiments, the metal layer 94 is treated to form a nitride layer 96, as shown in FIG. 7C. For example, a nitridation process, such as a nitrogen plasma process, can be performed on the metal layer 94 to convert the metal layer 94 into the nitride layer 96. In some examples, the metal layer 94 can be completely converted such that no metal layer 94 remains, while in other examples, a portion of the metal layer 94 remains unconverted such that the portion of the metal layer 94 remains with the nitride layer 96 on the metal layer 94. In some embodiments, silicon from the dielectric layers 62, 80 may diffuse into the nitride layer 96. As a result, the nitride layer 96 may include or be metal silicon nitride, such as TiSiN. The nitride layer 96 may have a thickness ranging from about 1 nm to about 3 nm, and a combined thickness of the nitride layer 96 and the silicide region 98 may range from about 5 nm to about 10 nm.

As shown in FIG. 7D, a metal liner 99 is formed on the nitride layer 96. In some embodiments, there may be a vacuum break between the nitridation process and the formation of the metal liner 99. As a result, the nitride layer 96 may also include oxygen. The metal liner 99 may include tungsten (W), platinum (Pt), tantalum (Ta), titanium (Ti), copper (Cu), cobalt (Co), ruthenium (Ru), rhodium (Rh), iridium (Jr), molybdenum (Mo), or other suitable metal. In some embodiments, the metal liner 99 includes W. The metal liner 99 may be formed by PVD and may have different thicknesses in different regions. For example, the portion of the metal liner 99 formed on the sidewall in the opening 82 may have a first thickness, and the portions of the metal liner 99 formed at the bottom of the opening 82 and over the dielectric layer 80 may have a second thickness substantially greater than the first thickness. In some embodiments, the first thickness ranges from about 0.5 nm to about 3 nm, such as from about 1.5 to about 2 nm, and the second thickness ranges from about 3 nm to about 10 nm. The metal liner 99 functions as an adhesion layer and a seed layer for a subsequently formed metal fill 102 (FIG. 7E).

In some embodiments, the PVD process to form the metal liner 99 may be a DC self-ionized PVD process. For example, the PVD process is performed in a process chamber with a chamber pressure ranging from about 0 mTorr to about 50 mTorr. The processing temperature ranges from about 20 degrees Celsius to about 450 degrees Celsius. The plasma source power (DC) ranges from about 1 kW to about 50 kW, and a plasma bias power ranges from about 0 kW to about 2 kW. The process gases may include Ar, Kr, or other suitable gases. The electro-magnets may be pull in or pull out for ion directional control.

In some embodiments, the PVD process to form the metal liner 99 may be an RF/DC PVD process. For example, the PVD process is performed in a process chamber with a chamber pressure ranging from about 0 mTorr to about 600 mTorr. The processing temperature ranges from about 20 degrees Celsius to about 450 degrees Celsius. The plasma source power (DC) ranges from about 0 W to about 100 W, the plasma source power (RF) ranges from about 1 kW to about 7 kW, and a plasma bias power ranges from about 0 W to about 200 W. The process gases may include Ar, Kr, or other suitable gases.

As shown in FIG. 7E, the metal fill 102 is formed on the metal liner 99 and fills the opening 82. The metal fill 102 includes the same material as the metal liner 99. However, the metal fill 102 is formed by CVD or ALD instead of the PVD process used to form the metal liner 99. The metal fill 102 formed by CVD or ALD fills the opening 82 better than a metal fill formed by PVD. A seam 104, or a void, is formed in the metal fill 102, but the seam 104 is substantially smaller than a seam in a metal fill formed by PVD. Because the metal liner 99 and the metal fill 102 are formed by different processes, the grain size of the metal liner 99 is different from the grain size of the metal fill 102. In some embodiments, the CVD or ALD to form the metal fill 102 process may be performed in a process chamber with a chamber pressure ranging from 1 Torr to about 300 Torr, and a processing temperature ranging from about 250 degrees Celsius to about 450 degrees Celsius. One or more precursors may be flowed into the process chamber. For example, WF₆ may be flowed into the process chamber at a flow rate ranging from about 1 sccm to about 450 sccm, and H₂ may be flowed into the process chamber at a flow rate ranging from about 1000 sccm to about 10000 sccm.

As shown in FIG. 7F, the portions of the metal fill 102, the metal liner 99, and the nitride layer 96 formed on the dielectric layer 80 are removed, and the portions of the metal fill 102, the metal liner 99, and the nitride layer 96 formed in the opening 82 are recessed. In some embodiments, the portions of the metal fill 102, the metal liner 99, and the nitride layer 96 formed on the dielectric layer 80 are removed by a planarization process, such as a CMP process. The portions of the metal fill 102, the metal liner 99, and the nitride layer 96 formed in the opening 82 are recessed by one or more etch processes. In some embodiments, the metal fill 102 and the metal liner 99 are recessed by a first etch process, such as a wet etch, a dry etch, or a combination thereof, and then the nitride layer 96 are recessed by a second etch process, such as a wet etch, a dry etch, or a combination thereof. The first etch process may be a selective etch process that does not substantially affect the dielectric layer 80 and the nitride layer 96. The second etch process may be a selective etch process that does not substantially affect the metal fill 102, the metal liner 99, and the dielectric layer 80. An opening 106 is formed as a result of the recessing of the portions of the metal fill 102, the metal liner 99, and the nitride layer 96. The opening 106 is defined by a portion 107 of a sidewall 105 of the dielectric layer 80. The bottom of the opening 106 includes the nitride layer 96, the metal liner 99, and the metal fill 102. In some embodiments, the top surfaces of the nitride layer 96, the metal liner 99, and the metal fill 102 may be substantially coplanar. In some embodiments, the top surfaces of the metal fill 102 and the metal liner 99 are located below the top surface of the nitride layer 96. In some embodiments, the top surface of the metal fill 102 is located below the top surfaces of the metal liner 99 and the nitride layer 96. In some embodiments, the top surface of the metal fill 102 is located below the top surface of the metal liner 99, which is located below the top surface of the nitride layer 96. The recessed metal fill 102 may have a height ranging from about 3 nm to about 10 nm. The opening 106 has a depth D1 ranging from about 3 nm to about 8 nm, such as about 5 nm. The opening 106 is filled with a metal cap 108 (FIG. 7G), which is formed using a PVD process. Thus, if the depth D1 is greater than about 8 nm, the metal cap 108 may not be able to fill the opening 106 without forming a seam. On the other hand, if the depth D1 is less than about 3 nm, the CMP process to remove the portions of the metal cap 108 formed on the dielectric layer 80 may remove all of the metal cap 108 formed in the opening 106.

As shown in FIG. 7F, the dielectric layer 80 includes the sidewall 105 including the portion 107, a portion 108, and a portion 111 connecting the portions 107 and 109. Prior to the recessing of the metal fill 102, the metal liner 99, and the nitride layer 96, the portion 107 and the portion 109 may be a continuous surface without the portion 111. The recessing of the metal fill 102, the metal liner 99, and the nitride layer 96 may also remove a portion of the dielectric layer 80, and the portion 111 is formed as a result. In some embodiments, the portion 109 has a first taper angle, the portion 111 has a second taper angle different from the first taper angle, and the portion 107 has a third taper angle different from the first and second taper angles. In other words, the portion 111 breaks the sidewall 105 into different portions having different taper angles. In some embodiments, the portion 111 is substantially parallel to a top surface of the dielectric layer 80. In some embodiments, the portion 111 is not present, and the portions 107, 109 have different taper angles.

As shown in FIG. 7G, the metal cap 108 is formed in the opening 106 and on the dielectric layer 80. The metal cap 108 includes the same material as the metal fill 102. However, the metal cap 108 is formed by PVD instead of the CVD or ALD process used to form the metal fill 102. The metal cap 108 formed by PVD fills the opening 106 better than a metal cap formed by CVD or ALD because the opening 106 is substantially shallower than the opening 82. The metal cap 108 is a seamless structure. Because the metal cap 108 and the metal fill 102 are formed by different processes, the grain size of the metal cap 108 is different from the grain size of the metal fill 102. In some embodiments, the grain size of the metal cap 108 is substantially greater than the grain size of the metal fill 102. Larger grain size can lead to reduced electrical resistivity. In some embodiments, the grain size of the metal cap 108 is substantially the same as the grain size of the metal liner 99, because both the metal cap 108 and the metal liner 99 are formed by PVD. In some embodiments, the grain size of the metal cap 108 ranges from about 40 nm to about 200 nm and the grain size of the metal fill 102 ranges from about 10 nm to about 40 nm. A seed layer is not present for forming the metal cap 108, because the metal cap 108 is formed by PVD. Because the metal cap 108 and the metal fill 102 include the same material, the interface between the metal cap 108 and the metal fill 102 is uni-grain. In some embodiments, the metal cap 108 has a width in the x-axis greater than a width of the metal fill 102. In some embodiments, a portion of the bottom surface of the metal cap 108 is disposed on the portion 111 of the sidewall 105 of the dielectric layer 80 (FIG. 7F).

In some embodiments, the PVD process to form the metal cap 108 may be a DC self-ionized PVD process. For example, the PVD process is performed in a process chamber with a chamber pressure ranging from about 0 mTorr to about 50 mTorr. The processing temperature ranges from about 20 degrees Celsius to about 450 degrees Celsius. The plasma source power (DC) ranges from about 1 kW to about 50 kW, and a plasma bias power ranges from about 0 kW to about 2 kW. The process gases may include Ar, Kr, or other suitable gases. The electro-magnets may be pull in or pull out for ion directional control.

In some embodiments, the PVD process to form the metal cap 108 may be an RF/DC PVD process. For example, the PVD process is performed in a process chamber with a chamber pressure ranging from about 0 mTorr to about 600 mTorr. The processing temperature ranges from about 20 degrees Celsius to about 450 degrees Celsius. The plasma source power (DC) ranges from about 0 W to about 100 W, the plasma source power (RF) ranges from about 1 kW to about 7 kW, and a plasma bias power ranges from about 0 W to about 200 W. The process gases may include Ar, Kr, or other suitable gases.

As shown in FIG. 7H, a planarization process is performed to remove the portion of the metal cap 108 formed on the dielectric layer 80. The planarization process may be a CMP process. The CMP process may remove a portion of the metal cap 108 formed in the opening 106. The remaining metal cap 108 may have a thickness ranging from about 2 nm to about 7 nm, such as from about 5 nm. The processes described in FIGS. 7B to 7H may be performed to form a conductive feature 110 having a bottom portion 112 and the metal cap 108 disposed on the bottom portion 112. As shown in FIG. 7H, the bottom portion 112 includes the nitride layer 96, the metal liner 99, and the metal fill 102. The nitride layer 96 is in contact with the sidewall of the dielectric layer 62 and a portion of the sidewall of the dielectric layer 80. In some embodiments, the nitride layer 96 is omitted, and the metal liner 99 is in contact with the sidewall of the dielectric layer 62 and a portion of the sidewall of the dielectric layer 80. The metal liner 99 is in contact with and surrounded by the nitride layer 96, and the metal fill 102 is in contact with and surrounded by the metal liner 99. The metal cap 108 is disposed on and in contact with the nitride layer 96 (if presented), the metal liner 99, and the metal fill 102.

The top surface of the conductive feature 110, which is the top surface of the metal cap 108, is free of a barrier layer, such as TiN or TaN. The material of the metal cap 108 has a lower electrical resistivity compared to TiN or TaN. As a result, contact resistance of the conductive feature 110 is reduced compared to conventional conductive features having TiN or TaN barrier layer as part of the top surface. The metal cap 108 provides a single grain interface to reduce interface resistance between a conductive feature disposed on the conductive feature 110 and the conductive feature 110. Furthermore, the metal cap 108 is seamless, which further reduces electrical resistance.

FIG. 7I is a cross-sectional side view of one of various stages of manufacturing the semiconductor device structure 100 of FIG. 1 taken along cross-section B-B, in accordance with some embodiments. In some embodiments, as shown in FIG. 7I, multiple epitaxy source/drain regions 56 are merged, and the silicide region 98 is formed on the merged epitaxy source/drain regions 56. The conductive feature 110 is formed on the silicide region 98 and the isolation regions 44. The conductive feature 110 includes the metal cap 108 disposed on the bottom portion 112, which includes the nitride layer 96, the metal liner 99, and the metal fill 102. After the formation of the conductive feature 110, an etch stop layer 210 is formed on the dielectric layer 80 and the conductive feature 110, and a dielectric layer 212 is formed on the etch stop layer 210. The etch stop layer 210 may include the same material as the CESL 60, and the dielectric layer 212 may include the same material as the dielectric layer 62. In some embodiments, the etch stop layer 210 includes SiN, and the dielectric layer 62 includes SiO₂. A conductive feature 214 is formed in the dielectric layer 212 and the etch stop layer 210 and is electrically connected to the conductive feature 110. In some embodiments, the conductive feature 214 is a conductive via. The conductive feature 214 may include the same material as the metal cap 108. In some embodiments, the conductive feature 214 includes W. With the metal cap 108 and the conductive feature 214 having the same material, a homogeneous interface is formed, which leads to reduced interface electrical resistance.

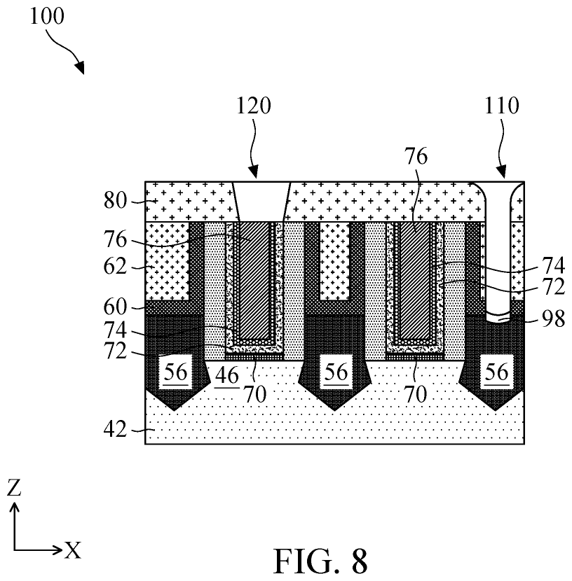

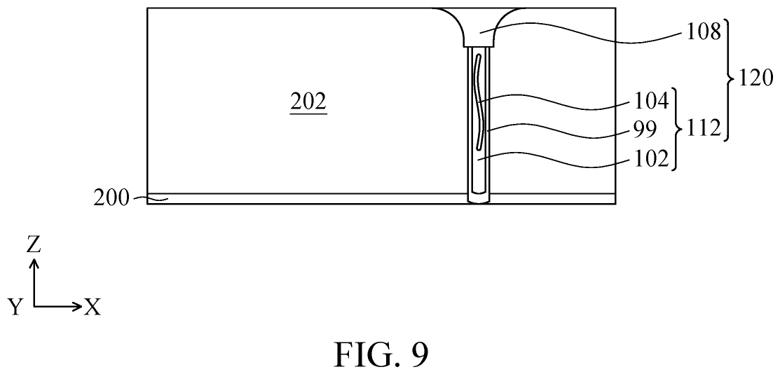

FIG. 8 is a cross-sectional side view of one of various stages of manufacturing the semiconductor device structure 100, in accordance with some embodiments. As shown in FIG. 8, the conductive feature 110 is formed in the CESL 60, the dielectric layer 62, and the dielectric layer 80. In some embodiments, a conductive feature 120 is formed in the dielectric layer 80 and is electrically connected to the gate conductive fill material 76. The conductive feature 120 may be the conductive feature 110 without the nitride layer 96.

FIG. 9 is a cross-sectional side view of the conductive feature 120 disposed in a dielectric layer 202, in accordance with some embodiments. As shown in FIG. 9, the dielectric layer 202 is disposed on an etch stop layer 200, and the conductive feature 120 is disposed in the etch stop layer 200 and the dielectric layer 202. In some embodiments, the dielectric layer 202 may be the dielectric layer 80, the conductive feature 120 is in contact with the gate conductive fill material 76, and the etch stop layer 200 is not present. In some embodiments, the dielectric layer 202 may be an intermetal dielectric (IMD), which is a part of an interconnect structure disposed over the dielectric layer 80, and the conductive feature 120 may be a conductive line or a conductive via. As shown in FIG. 9, the conductive feature 120 includes the bottom portion 112, which includes the metal liner 99 and the metal fill 102 (the nitride layer 96 is not present), and the metal cap 108 disposed on the bottom portion 112. The metal liner 99 is in contact with the sidewall of the dielectric layer 202 and a conductive feature (not shown) disposed there below, and the metal fill 102 is in contact and surrounded by the metal liner 99. The conductive feature 120 (or the conductive feature 110) may have a critical dimension in the x-axis ranging from about 10 nm to about 200 nm, such as from about 10 nm to about 60 nm, and a critical dimension in the y-axis ranging from about 10 nm to about 5 microns.

The present disclosure in various embodiment provide the semiconductor device structure 100 and the methods of forming the same. In some embodiments, the semiconductor device structure 100 includes a conductive feature 120. The conductive feature 120 includes a bottom portion 112 and a metal cap 108 disposed on the bottom portion 112. The bottom portion 112 includes a metal liner 99 and a metal fill 102 in contact and surrounded by the metal liner 99. Some embodiments may achieve advantages. For example, the contact resistance of the conductive feature 120 is reduced because the top surface of the conductive feature 120 is barrier free. Furthermore, the method to form the conductive feature 120 is simple and is a low-cost method.

An embodiment is a semiconductor device structure. The structure includes a dielectric layer disposed over an epitaxy source/drain region and a conductive feature disposed in the dielectric layer. The conductive feature includes a metal liner including a first material and a metal fill surrounded by the metal liner. The metal fill includes the first material having a first grain size. The conductive feature further includes a metal cap disposed on the metal liner and the metal fill, and the metal cap includes the first material having a second grain size different from the first grain size.

Another embodiment is a semiconductor device structure. The structure includes a gate conductive fill material, an epitaxy source/drain region disposed on one side of the gate conductive fill material, a first dielectric layer disposed over the epitaxy source/drain region, a dielectric layer disposed over the first dielectric layer, and a conductive feature disposed in the first dielectric layer and the second dielectric layer. The conductive feature includes a metal liner disposed in the first dielectric layer, a metal fill in contact with the metal liner, and a seam located in the metal fill. The structure further includes a metal cap disposed on the metal liner and the metal fill, and the metal cap is seamless.

A further embodiment is a method. The method includes forming a first opening in a dielectric layer disposed over an epitaxy source/drain region, forming a metal liner in the first opening by a first process, and forming a metal fill to fill the first opening by a second process different from the first process. A seam is formed in the metal fill. The method further includes recessing the metal liner and the metal fill to form a second opening and forming a metal cap to fill the second opening with a third process different from the second process. The metal cap is seamless.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a dielectric layer disposed over an epitaxy source/drain region; and
a conductive feature disposed in the dielectric layer, the conductive feature comprises:
a metal liner comprising a first material;
a metal fill surrounded by the metal liner, wherein the metal fill comprises the first material having a first grain size; and
a metal cap disposed on the metal liner and the metal fill, wherein the metal cap comprises the first material having a second grain size different from the first grain size.

2. The semiconductor device structure of claim 1, wherein the first material comprises tungsten, platinum, tantalum, titanium, copper, cobalt, ruthenium, rhodium, iridium, or molybdenum.

3. The semiconductor device structure of claim 1, wherein the first material comprises tungsten.

4. The semiconductor device structure of claim 3, further comprising a nitride layer in contact with the dielectric layer, wherein the nitride layer surrounds the metal liner, and the metal cap is disposed on the nitride layer.

5. The semiconductor device structure of claim 4, wherein top surfaces of the nitride layer, the metal liner, and the metal fill are substantially coplanar.

6. The semiconductor device structure of claim 4, wherein the nitride layer comprises TiSiN.

7. The semiconductor device structure of claim 4, further comprising a silicide region in contact with the epitaxy source/drain region, wherein the nitride layer is in contact with the silicide region.

8. The semiconductor device structure of claim 1, wherein the metal fill further comprises a seam.

9. A semiconductor device structure, comprising:
a gate conductive fill material;
an epitaxy source/drain region disposed on one side of the gate conductive fill material;
a first dielectric layer disposed over the epitaxy source/drain region;
a second dielectric layer disposed over the first dielectric layer; and
a conductive feature disposed in the first dielectric layer and the second dielectric layer, wherein the conductive feature comprises:
a metal liner disposed in the first dielectric layer;
a metal fill in contact with the metal liner, wherein a seam is located in the metal fill; and
a metal cap disposed on the metal liner and the metal fill, wherein the metal cap is seamless and is in contact with the second dielectric layer.

10. The semiconductor device structure of claim 9, further comprising an etch stop layer disposed between the first ILD and the epitaxy source/drain region, wherein the conductive feature is disposed in the etch stop layer.

11. The semiconductor device structure of claim 9, wherein the metal liner, the metal fill, and the metal cap comprise a same material.

12. The semiconductor device structure of claim 11, wherein the metal liner, the metal fill, and the metal cap comprise tungsten, platinum, tantalum, titanium, copper, cobalt, ruthenium, rhodium, iridium, or molybdenum.

13. The semiconductor device structure of claim 11, wherein the metal liner, the metal fill, and the metal cap comprise tungsten.

14. The semiconductor device structure of claim 9, further comprising a nitride layer in contact with the first dielectric layer, wherein the metal liner is disposed on the nitride layer.

15. The semiconductor device structure of claim 14, wherein the nitride layer comprises TiSiN.

16. A method, comprising:
forming a first opening in a dielectric layer disposed over an epitaxy source/drain region;
forming a metal liner in the first opening by a first process;
forming a metal fill to fill the first opening by a second process different from the first process, wherein a seam is formed in the metal fill;
recessing the metal liner and the metal fill to form a second opening; and
forming a metal cap to fill the second opening with a third process different from the second process, wherein the metal cap is seamless.

17. The method of claim 16, further comprising a forming a nitride layer on a sidewall of the first opening, wherein the metal liner is formed on the nitride layer.

18. The method of claim 17, further comprising recessing the nitride layer, wherein the metal cap is formed on the nitride layer.

19. The method of claim 16, wherein the first process is a physical vapor deposition process, the second process is a chemical vapor deposition process or an atomic layer deposition process, and the third process is a physical vapor deposition process.

20. The method of claim 16, wherein the second opening has a depth ranging from about 3 nm to about 8 nm.
